(19) United States
(12) Patent Application Publication
(10) Pub. No.: US 2006/0150903 A1
(43) Pub. Date: Jul. 13, 2006

(54) Method and apparatus for processing substrates

(76) Inventor: Othmar Zuger, Triesen (CH)

Correspondence Address: NOTARO AND MICHALOS, 100 DUTCH HILL ROAD, SUITE 110, ORANGEBURG, NY, 10962-2100, US

(21) Appl. No.: 10/530,822

(22) PCT Filed: Oct. 15, 2003
(86) PCT No.: PCT/CH03/00673

§ 371 Date: Aug. 15, 2005

(30) Foreign Application Priority Data
Oct. 15, 2002 (US) 60418672

(51) Int. Cl. B05C 11/00; C23C 16/00

(52) U.S. Cl. 118/663; 427/248.1

(57) ABSTRACT

Method and apparatus for processing substrates are described. An apparatus for processing a substrate according to the present invention includes a source for processing the substrate. A sensor generates a sensor signal that is related to a state of the substrate. A source controller is coupled to the sensor and is coupled to the source. The source controller generates a control signal that is related to the sensor signal and that modifies at least one operating parameter of the plasma source during the processing of the substrate.

This application relates to published application number WO 00/71774 A1, concerning power modulation of coating sources to achieve a fixed profile of the coating thickness on the substrates (correction of chord effect, thickness gradient coatings). Precision optics dichroic filter coatings require increasingly demanding uniformity levels of the coatings (thickness, index of refraction). In applications like projection display components, uniformities on the level of a few 0.1% to some fraction of 1% over several 1000 cm² have to be achieved for efficient mass production of color filters. For applications in the field of optical data transmission (telecommunication filter coatings like DWDM technology), extreme uniformity requirements on the level of ˜0.01% have to be achieved over at least several 10 cm2 for filters consisting of more than 100 layers and process times, depending on the process technology, of 12 to up to about 50 hours.

### BACKGROUND OF THE INVENTION

Masking techniques, special gas supply techniques, special magnet configurations with sputtering magnetrons are used to statically optimize the coating uniformity achievable on the substrates.

A high degree of thickness uniformity is usually achieved by repetitively moving the substrates past the coating source, e.g. by using rotating drum, dome or disc as a substrate holder, or with single substrate coating, by using a rotating stage where the substrate rotated on its own (rotational symmetry) axis.

Additionally, dynamical averaging techniques for the vapor distribution of the source are used for improving the coating uniformity, like laterally scanning of the e-beam in evaporator sources or rotating or cyclic linear motion magnet systems in sputtering magnetrons.

The limits of the uniformity achievable with these techniques are determined by:

I) limited accuracy of the mechanical motion of the substrates,

a) static accuracy (adjustment of rotation axis for example with respect to source, tilting of substrates): These inaccuracies result in a static inhomogeneity of the coating thickness on the substrates (i.e. these effects are reproduced in each batch). Viewed from a point moving with the ideal substrate position, these inaccuracies lead to a synchronous deviation of the ideal source position with a fixed amount, i.e. both the phase and the amplitude of this variation are static.

b) dynamic accuracy: wobbling, precession, mechanical play of bearings, etc. Viewed from a point moving with the ideal substrate position, these effects represent an asynchronous variation of the source position with an amount that is dynamically changing, i.e. neither the phase nor the amplitude are ‘predictable’ in the sense that they are in fixed phase relation to the substrate motion.

To give a more specific example, deviation of the subtrate to source distance can for example result from:

i) substrate-source distance variations: coating rate on substrates decreases (increases) with increasing (decreasing) distance between source and substrate. Possible causes of distance variations: precession of the substrate holder disc axis because of assymetric mass distribution on the disk (even with perfect radial balancing), clearance of the bearing (advantageously for maintaining a constant rotation speed, see c)) and more.

ii) radial motion: coating rate on substrates decreases (increases) with increasing (decreasing) momentary radius of the axial motion. Possible causes: rotation axis of the substrate disc is momentarily displaced from its ideal position because of improper balancing of disc or alike.

iii) axial speed variations: coating rate on substrates decreases (increases) with increasing (decreasing) angular velocity of the substrates on their rotational motion path. Possible causes: varying frictional forces on the bearing at different anglular positions (see a)), not well controlled speed of the driving motor, instability of the speed loop control of the rotary drive and more.

A high degree of precision of the substrate motion can be achieved by using high precision parts for the substrate holder and drive, elaborate adjustments of all parts and a sophisticated mechanical design. However, such solutions will not only be very expensive to set up, but also very delicate to operate. Caused by these facts, the operation costs will be high and the system will have a limited robustness which is a key requirement in a mass production environment. As a consequence, such a system will have a limited uptime and a high sensitivity to final product yields. Also, any changes or improvements on such a system might be difficult to implement due to its complexity (limited flexibility).

II) Fluctuations at the coating source itself:

These can originate from instability of the material vapor flux distribution from the coating material source, either intrinsic (stochastic) or caused by backaction from the substrates (synchronous or asynchronous). Other sources for fluctuations are instable temperature of the coating material in the coating source (nonstable cooling, intrinsic thermal drifts, especially at an early stage of a coating process) which can cause changes in the coating rate (drifts), fluctuations of the electric power applied to the target, caused by arcing (statistic) etc., drifts of the coating rate due to the progressive erosion of the coating material amount in the coating source (e.g. target in case od sputtering) over its lifetime (i.e. changes in the target surface geometry cause variations of the material flow characteristics from the target).

III) Variations in film growth kinetics on the substrates due to drifting temperatue or temperature gradients across the substrates.

IV) Residual gas pressure drifts (e.g. from outgassings at an early stage of the process) can result in changes in the local pressure distribution at the source inducing drifts in the material flow distribution from the source (residual gas drifts are usually continuously decreasing during batch process, mainly H₂O as the dominant part of residual gas is acting as an additional source of oxygene as the reactive gas)

U.S. Pat. No. 6,128,087 uses an online spectrometer system in an inline coating system for CRT tube anti-reflection coating. The optical response from each CRT tube coated is analysed and the so determined layer thicknesses are used for correcting the process for successive tubes to be coated. The disadvatage is that the correction only helps for the successive tubes and immediate statistical inaccuracies or fluctuations cannot be corrected at all. Additionally, the method is not applied to uniformity, but the control system is used instead of an online optical monitoring measuring the thickness during the growth of the layers.

There are a number of patents proposing the use of masks or shields in order to realize better uniformity. (U.S. Pat. No. 6,254,934 proposes movable shieldings driven by a stepper motor. U.S. Pat. No. 6,375,747 decribes adjustable shieldings accessible from non-vacuum side and U.S. Pat. No. 5,156,727 discloses externally adjustable masks for inline sputtering sources.)

In U.S. Pat. No. 6,063,436 for example different masks are used for each coating material. These masks are externally interchangeable. However no active control of a parameter is described.

In U.S. Pat. No. 4,543,910 the use of externally moveable shields is described in order to adjust uniformities. Without specifying in detail, the use of thickness sensing means is proposed to automatically control the shields via motors driving the shields. However since the mechanical adjustment of masks or shields is a rather slow process (the mechanical adjustment speed is limited by mechanical resonance frequencies of the setup), uniformity adjustment can only be performed on an integral level, i.e. on a overall coating process level. Nothing is said on how fast fluctuations and/or statistical inaccuracies can be handled.

### SUMMARY OF THE INVENTION

It is subject of the present invention to disclose a method for coating substrates which allows the precise control of coating thicknesses and coating thickness distributions across the substrates to be coated (the term thickness is used in the sense of an “effective” thickness, e.g. for optical coatings, the optical thickness (physical thickness*index of refraction) is one of the the relevant parameter for the performance of the coating). It is as well subject of the present invention to disclose a coating apparatus in which such a coating method is implemented.

### DETAILED DESCRIPTION OF THE INVENTION

The core of the present invention is the idea not to try to eliminate the hard to control inaccuracies and fluctuations which cause variations of the deposition rate in the coating system, but to regulate the deposition rate online by adequate means to compensate for the effects of these fluctuations or inaccuracies on the deposition rate, or coating thickness, which is mathematically described by the temporal integral of the coating rate. In general this compensation can be realized with two different approaches: If a coating parameter is known to be fluctuating or to comprise inaccuracies during the deposition run and the influence of these inaccuracies or fluctuations on the deposition rate is known, this parameter can be monitored online during the deposition and adequate means can be used to counter react, with the result of a compensation of the effect of these inaccuracies or fluctuations on the coating thickness distribution. Such a method will be named ONLINE COMPENSATION.

The second possibility is to monitor the deposition rate (or its time-integral being the coating thickness) for different positions on the substrate directly, and without necessarily knowing the source or cause of monitored fluctuations of the deposition rate or the depostion thickness as the integral of the rate it can be corrected by adequate means. This results in an online correction of the deposition rate. Measuring and correction of the deposition rate leads to a closed loop and therefore such a method is named ONLINE CLOSED LOOP CORRECTION.

It is subject matter of the present invention that the adequate means which need to be regulated for compensating inaccuracies or fluctuations can be regulated with a time constant small compared to the time constant of the sources of uncontrolled fluctuations in the deposition rate.

Following now is a detailed description of different embodiments of the present invention with the aid of examples and figures

a) Online Compensation

This can be realized by dynamic variation (on-line) of the coating source performance (rate, vapor distribution, etc.) by varying externally accessible parameters of the source (e.g. power, gas feeding system, magnet motion for magnetrons, moveable apertures, etc.), driven for example by a detection signal representing the actual position of the substrates with respect to the coating source. The purpose of this control system is an instantaneous compensation of coating thickness deviations on the substrates, caused by deviations of the substrate motion from the ideal path with respect to the coating source. Since the compensation concept is an online reaction to an actually occurring deviation, the entire loop starting from the detection, making the comparison to a setpoint, generating and feeding the reaction signal through the source supply to the coating source and finally resulting in a controlled variation of the coating rate or its distribution has to be faster than the occurrence of the deviations itself, otherwise, the reaction occurs at the wrong position of the substrates. Thus, speed is a crucial factor for proper compensation, especially the speed of accessing the coating rate or distribution at the source is the determining factor of the compensation.

As an example, the deviation of the substrate to source distance from the value of the nonperturbed path is used for a controlled variation of the target power determining the actual coating rate of the source, compensating the coating thickness error that would occur if the power would be constant.

An important condition for the compensation concept is the stabililty of the rest of the coating system with respect to variation of the coating thickness. The coating rate is formally determined as a function of all relevant process parameters:
rate at substrate=f(distance source-substrate, substrate speed, Power, Gasflow, etc)

As an example, in the case of compensation of deviations of the source-substrate distance by varying the power, the substrate speed and the gasflows have to be constant in order that the compensation can be performed in a correct manner. The varation ΔP of the power is directly determined by the deviation Δd of the distance, the dependence of the rate on these two parameters is however additionally dependent on other parameters. All these other parameters have to be (sufficiently) constant not to change the dependences of the compensation parameters. However in principle it is possible to use two or more compensation parameters, for example if a rough compensation, performed by one compensation parameter is followed by a fine compensation performed by another compensation parameter. Again the compensation speed is very important in order to really compensate.

Conceptually, multiple parameter deviations can be monitored and used to compensate for coating thickness deviations by one other parameter. For example, both the source-substrate distance deviations and the substrate speed deviations can induce a power variation in a combined way for compensating thickness errors that would occur if the power were kept constant. Again, all the other relevant parameters must be constant to achieve a correct compensation.

Although this invention is focused on dichroic optical coatings produced by a physical vapor deposition method, the compensation scheme applies to all coating methods and especially to those that either cyclically move the substrates to pass a coating source during the growth of the coating, or continuously rotate the substrates about its own axis during the coating process.

A well suited compensation parameter is the power applied the coating source determining the coating rate. In the case of DC, pulsed-DC or RF magnetron sputtering, the delay of variations on the coating rate through the power is mainly determined by the speed of the power supplies. With todays power supply technologies of commercially available power supplys, small output level variations (in the up to several 10% range of the static level) can be achieved with delays of 10 ms or smaller, allowing compensations of deviations in the low 10 ms range, assuming detection signal delays also in the milisecond range (low pass filtering of detection signals to improve the signal-to-noise ratio and, thus, the precision of the deviations signals, always results in delays). With pulsed-DC technologies, used in reactive mid-frequency magnetron sputtering because of the digital nature of pulsing and the pulse cycle times in the 10 μs range, variations in the pulse trains can be done in the ms-range. Similarily for Rf sputtering, due to the low Q in matching networks, variations of the Rf power levels can occur in the ms-range.

Beside the variations of the power, fast rate (or distribution of it) adjustments could be achieved by modifications of the magnetic fields if electromagnets can be used as field varation devices. Local gasflow variations can also induce changes in the source rate or its distribution (e.g. by using a multiport gas inlet systems with more than one feeding line and a separate valve for each feeding line or feeding line sections of the multiport gas inlet system). The source rate depends on the local gas pressure distribution at the source surface. The time constants for these local pressure variations are determined by the pumping speed of the reactive process and the pump. For high rate reactive sputter processes and system geometries, the time constants can be in the 10 msec up to the 1 sec range, dependent on process chamber volume and geometry, vacuum pumps and coating rate of the source (the time constant is defined as chamber volume divided by the total pumping speed). These time constants are slower than possible rate changes induced by the power changes, thus allowing a compensation

The compensation concept specifically used with the power as the compensating parameter has to be considered as a significant improvement over WO 00/71774 A1 concerning power modulation of coating sources to achieve a fixed profile of the coating thickness on the substrates (correction of chord effect, thickness gradient coatings). In this former invention, coating thickness profiles were superimposed onto the substrates, either to correct for systematic non-uniformities (chord effect), or to generate desired profiles. The superposition is a statical process in the sense that it is a correction to a statically occurring effect determined by the coating system geometry.

One aspect of this invention is the use of an instantaneous detection signal representing the actual position and/or orientation (or more precise, the actual deviation from the ideal position and/or orientation) of the substrates to dynamically vary the actual coating rate of the source in order to compensate for the non-uniformities that would occur if nothing would be varied. Thus, the main difference to the former idea is the compensation of effects that do not predictably occur, i.e. through the monitoring of deviations of relevant process parameters (e.g. source-substrate distance) and the immediate reaction in a compensation on another parameter, the system dynamically adapts to a non-permanent situation and, thus, a significantly improved robustness of the coating process can be achieved.

More specifically, in the publication WO 00/71774 A1, the focus is set onto the variation of the coating rate at the source in a synchronuous modulation of the coating rate according to a predefinded profile, i.e. at a fixed phase and a fixed amplitude with respect to the substrate motion. In the present invention, the idea is extended to the case of using the power variation in a dynamic way, i.e. to vary the coating rate according to a control signal generated from monitored deviations of the substrate positions with respect to the source from its ideal positions on the path of passing the source. The AM or/and FM modulations with a dynamically adapted AM amplitude and/or FM amplitude would be one example of this extension.

### DESCRIPTION OF THE DRAWINGS

In FIG. 1 shown is the schematic setup of a coating system online compensation system 1. This system comprises a coating source 3, controlled by the coating source supply 5 which typically regulates coating parameters such as power, gasflow, magnet motion etc. This coating source supply 5 itself is regulated by an additional controller 7 which receives signals form a substrate position detector 13.

FIG. 2 shows a coating apparatus according to the present invention comprising an optical thickness detection system enabeling the online closed loop correction method.

In the previous examples the position of the substrate relative to the source was monitored and used for compensating thickness non-uniformities that would occur without compensation. In a generalization other coating parameters can be monitored and used for compensation.

b) Online Closed Loop Correction

Dynamic variation (on-line) of the coating source performance (rate, vapor distribution, etc.) by varying externally accessible parameters of the source (e.g. power, gas feeding system, magnet motion, moveable apertures, etc.), driven by a correction signal deduced from the optical response of the substrates measured online at preferably more than one position on the substrates before passing the coating source. The term “substrate” does not delimit the applicability of the invention to a single element, but encompasses also a plurality of substrates or a set of substrates the coating unit is loaded with. The purpose of this control loop system is an instantaneous correction of deviations in the optical performance. This is not limited to coating thickness, although it will usually be most relevant parameter. Variations in optical index of the coating might also be possible. For intermediate index material coating like silicon oxynitride (SiOxNy), the index can be kept constant by using the the N2-O2 gasflow mixture ratio as a variation parameter. For mixed material coating from a two source setup, the ratio between the individual rates has to be used as a variation parameter. It is especially interesting and subject matter of the present idea to perform an instantaneous correction of deviations in the optical performance of the coating at different positions on the substrates during the built up of the coating layers.

As an example, the differences in the optically spectral response at two substrates consecutively passing the source are used for a controlled variation of the target power determining the actual coating rate of the source, correcting the optical response differences by applying different coating rates when the substrates are passing the source.

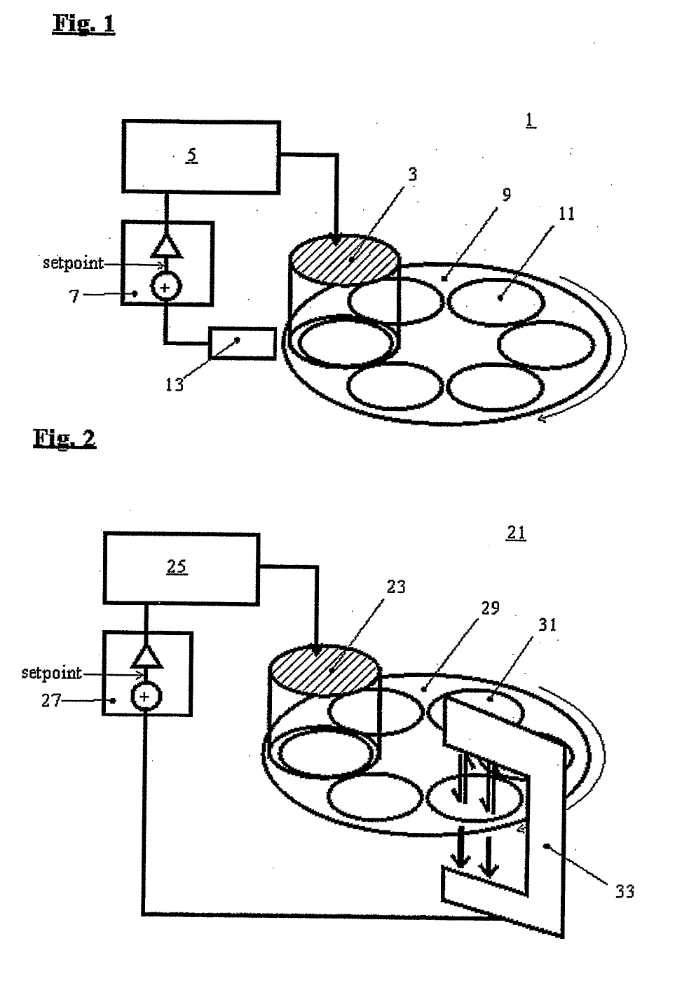

In FIG. 2 shown is the schematic setup of a coating system 21 with online closed loop correction. This system comprises a coating source 23, controlled by the coating source supply 25 which typically regulates coating parameters such as power, gasflow, magnet motion etc. This coating source supply 25 itself is regulated by an additional controller 27 which receives signals from a thickness detection system 33. This thickness detection system can be realized by measuring the actual optical transmission and/or reflection characteristic of the substrate at more than one position on the substrates. A multiple detector system is required for measuring the uniformity at least approximately perpendicular to the direction of motion of the substrates.

In a generalization of this concept, the control of the optical uniformity is a special case of a controlled lateral profile of the optical response on the substrates (case with the setpoint for a difference in the response equal to zero). To achieve a special profile, the difference setpoint has to be modified synchronously with the substrate moving past the coating source, where the modification is determined by the desired profile.

Since the control scheme requires an in-situ and online thickness detection system of substrates that cyclically pass the coating source during the growth of the layers, its application is essentially limited to optical coatings only. In a straitforward extension, it can also be used for non-optical coatings in its function if the thickness can be detected by optical means. It could also applied to any other type of coating, if there is a specific method for online detection of a response reflecting the thickness or composition of the growing layers.

In the example the optical thickness detection system is based on spectral optical responses (R(λ) or T(λ)) of the coating that are synchronously measured with the substrate motion at different positions on the substrate (note that, with moving substrates, there are not several detectors required along the direction of motion, different positions can be accessed through different timings of the detection when the substrates pass the detector).

Since the optical responses mainly depend on optical phase factors phi˜n·d/λ of the individual layers, where n is the index of refraction of the coating layer, d is the physical thickness of the layer and λ is the wavelength of the light, differences in the optical thickness Δ(n·d) are dominantly reflected in spectral shifts Δλ of the responses. Thus, the relevant thickness deviations Δ(n·d) being the input for the control system can be accessed through the spectral shifts of the online measured spectras. Crucial for the control system's performance (accuracy and stability) will be the algorithms for the unambigous extraction of Δ(n·d) from the spectras.

c) Comparing the Online Closed Loop Correction to the Online Compensation

The main difference of the online closed loop correction scheme to the online compensation scheme is the type of deviation that is measured for generating a correction at the source. In the online closed loop correction scheme, by online measuring and comparing the actual optical response of the coating at different positions on the substrates during the coating process, the uniformity as the parameter to be maintained constant is directly measured and its deviations give rise to a reaction at the coating source through the controller in order to compensate the effect of some not detected cause of non-uniformity. Thus, in contrast to the compensation scheme, the cause of the non-uniformity does not have to be known, the control loop in the correction scheme always minimizes the non-uniformities, indepenent of its cause. Additionally, there is not a seperate detection required for each effect as in the online compensation scheme, all effects causing a thickness non-uniformity are directly corrected by the controlled variation at the source based on the measured thickness non-uniformity.

This advantage however comes with the demanding task of finding proper algorithms and components to have an acceptable stability range of the closed control loop. The unambigous generation of correction signals from the different response spectras and the internal delays (fast and synchronous detection of optical spectras, intrinsic delays in all components of the control loop, including the response of the coating rate distribution) will be crucial for the proper operation of the control loop.

There is however a relaxed requirement on the speed of the online closed loop correction. Since the uniformity of the absolute (optical) thickness of the layers is the crucial parameter for an uniform optical response of the coating, a uniformity deviation detected at an early stage of a layer can be corrected with some delay as long as the correction is done before the end of the layer. More specifically, since the uniformity of the thickness is the time-integral of the uniformity of the (effective) rate from the source during the coating process, the correction can be done with a delayed counter non-uniformity in the rate distribution of the source. However, such delayed action might require large variations on the rate distribution to achieve the full correction. Since large variations are usually less accurate, the resulting correction will also be less accurate. From the compensation point of view at the source, immediate reaction is preferable. On the other hand, the detection accuracy of the non-uniformity will increase as the layers become thicker during the coating process. Thus, from the detection point of view, delayed reaction would be preferable. In an implementation of the online closed loop correction scheme, non-linear means like adaptive limitations of the correction range etc. can be applied in order to achieve a highly reliable stability of the closed loop (Fuzzy Controller Concepts).

d) General Advantage of a Compensation Scheme (Online Compenstaion or Online Closed Loop Correction)

There are several technical advantages of using a compensation or control scheme to overcome uniformity problems:

1) With a simplifed mechanical design and lower tolerance parts in the implementation, a similar precision in the coating uniformity can be achieved as with a more sophisticated design and more precise parts, both giving a cost advantage in the realization.

2) A simpler mechanical design usually results in a higher robustness of the system (lower rate of failures) and, as a consequence, a better reliability of the processes run with such a system. Both advantages results in a cost advantage in the operation of such a system.

3) With a properly tuned compensation or feedback control system, the coating yield will be statistically higher, because there is a online correction active that will reduce the impact of process fluctuations and drifts on the quality of the final product.

4) A combination of both a high precision design and an active control using rate modulations to compensate for thickness deviations can enable a reliable production of high precision filter coatings that cannot be reliably made without this combination (e.g. DWDM filters with 50 GHz spacing, etc.)

To summarize in a general way the invention relates to an apparatus for coating a substrate, the apparatus comprising:

a coating source for processing the substrate;

a sensor that generates a sensor signal at an output that is related to a the actual status of the coating process; and

means for generating a control signal related to the sensor signal for modifying at least one operating parameter of the coating source during the processing of the substrate, wherein the sensor signal does not reflect the at least one operating parameter.

The actual status of the coating process can comprise coating parameters of the coating process as well as actual characteristics of the film coated on the substrate.

Such an apparatus can be used to perform a method for processing a substrate, the method comprising:

a) processing the substrate in a treatment area of a treatment source substantially according to a predetermined scheme comprising a set of parameters;

b) selecting a subset of said set with at least one parameter as control parameter(s) and at least one further parameter not comprised in said subset as operating parameter(s);

c) determining a deviation of the subset from the predetermined scheme;

d) generating a control signal in response to the determined deviation; and

e) modifying the at least one operating parameter(s) in response to the control signal to compensate for an effect of the deviation from the predetermined scheme.

What is claimed is:

1. An apparatus for coating a substrate, the apparatus comprising:
a coating source for processing the substrate;
a sensor that generates a sensor signal at an output that is related to a the actual status of the coating process; and
means for generating a control signal related to the sensor signal for modifying at least one operating parameter of the coating source during the processing of the substrate, wherein the sensor signal does not reflect the at least one operating parameter.

2. A method for processing a substrate, the method comprising:
processing the substrate in a treatment area of a treatment source substantially according to a predetermined scheme comprising a set of parameters;
selecting a subset of said set with at least one parameter as control parameter(s) and at least one further parameter not comprised in said subset as operating parameter(s);
determining a deviation of the subset from the predetermined scheme;
generating a control signal in response to the determined deviation; and
modifying the at least one operating parameter(s) in response to the control signal to compensate for an effect of the deviation from the predetermined scheme.
